(19) United States
(12) Patent Application Publication
(10) Pub. No.: US 2014/0263182 A1
(43) Pub. Date: Sep. 18, 2014

(54) DC PULSE ETCHER

(71) Applicant: TOKYO ELECTRON LIMITED, Tokyo (JP)

(72) Inventors: Lee Chen, Cedar Creek, TX (US); Radha Sundararajan, Dripping Springs, TX (US)

(73) Assignee: TOKYO ELECTRON LIMITED, Tokyo (JP)

(21) Appl. No.: 13/837,391

(22) Filed: Mar. 15, 2013

(51) Int. Cl. H01J 37/32

(52) U.S. Cl. CPC H01J 37/32009
USPC 216/71; 216/67; 156/345.1

(57) ABSTRACT

A method of selectively activating a chemical process using a DC pulse etcher. A processing chamber includes a substrate therein for chemical processing. The method includes coupling energy into a process gas within the processing chamber so as to produce a plasma containing positive ions. A pulsed DC bias is applied to the substrate, which is positioned on a substrate support within the processing chamber. Periodically, the substrate is biased between first and second bias levels, wherein the first bias level is more negative than the second bias level. When the substrate is biased to the first bias level, mono-energetic positive ions are attracted from plasma toward the substrate, the mono-energetic positive ions being selective so as to enhance a selected chemical etch process.

### FIELD OF THE INVENTION

The present invention is related to plasma processing systems and, more specifically to plasma processing systems and methods for substrate etching.

### BACKGROUND OF THE INVENTION

During semiconductor processing, plasma is often utilized to assist etch processes by facilitating the anisotropic removal of material along fine lines or within vias or contacts patterned on a semiconductor substrate. Examples of such plasma-assisted etching include reactive ion etching (“RIE”), which is in essence an ion-activated chemical etching process.

Although RIE has been in use for decades, its maturity is accompanied by several negative features, including: (a) broad ion energy distribution (“IED”); (b) various charge-induced side effects; and (c) feature-shape loading effects (i.e., micro loading). For example, a broad IED contains ions that have either too little, or too much, energy to be useful, the latter of which is susceptible to causing substrate damage. Additionally, the broad IED makes it difficult to selectively activate desired chemical reactions, where side reactions are often triggered by ions of an undesired energy. Further, positive charge buildup on the substrate may occur and repel ion incident onto the substrate. Alternatively, the charge buildup may produce local charge differences that affect damaging currents on the substrate. Charge buildup may be due, in part, to the RF energy used to produce a negative bias on the non-conductive substrate or on the chuck, or table, used to support the substrate and attract positive ions from the plasma. Such RF frequencies are typically too high to allow positive or near neutral potential to exist for a sufficient time to attract electrons to neutralize the positive charges accumulated on the substrate. Non-uniform accumulation of charge across the surface of the substrate may create potential differences that can lead to currents on the substrate that can be damaging to devices being formed.

One known, conventional approach to addressing these problems has been to utilize neutral beam processing. A true neutral beam process takes place essentially without any neutral thermal species participating as the chemical reactant, additive, and/or etchant. The chemical etching process at the substrate, on the other hand, is activated by the kinetic energy of the incident, directionally energetic neutral species. The incident directional, energetic, and reactive neutral species also serve as the reactants or etchants.

One natural consequence of neutral beam processing has been the absence of micro-loading. That is, because of the process in which the thermal species that serve as etchants in RIE, there is relative little flux-angle variation in the incident neutral species. However, the lack of micro-loading results in an etch efficiency, or maximum etching yield, of unity, in which one incident neutral nominally prompts only one etching reaction. But with RIE, the abundant thermal neutral etchant species may all participate in the etching of the film, where the activation by one energetic incident ion may achieve an etch efficiency of 10, 100, and even 1000, while being forced to live with micro-loading.

The separation of ionization and chemistry may be achieved if the voltage applied to the RF electrode is on the order of 1.5 kV and self-bias voltage on the order of −700 V. However, many processes, and devices, are intolerant of high ion-energy.

While many attempts have been made to cure these shortcomings, i.e., etch efficiency, micro-loading, charge damage, etc., there still remains, and the etch community continues to explore, novel, practical solutions to this problem.

### SUMMARY OF THE INVENTION

The present invention overcomes the problems and other shortcomings of the prior art plasma etching systems set forth above.

According to one embodiment of the present invention, a method of selectively activating a chemical process using a DC pulse etcher is performed in a processing chamber having a substrate therein for chemical processing. The method includes coupling energy into a process gas within the processing chamber so as to produce a plasma containing positive ions. A pulsed DC bias is applied to the substrate, which is positioned on a substrate support within the processing chamber. Periodically, the substrate is biased between first and second bias levels, wherein the first bias level is more negative than the second bias level. When the substrate is biased to the first bias level, mono-energetic positive ions are attracted from plasma toward the substrate, the mono-energetic positive ions being selective so as to enhance a selected chemical etch process.

Another embodiment of the present invention includes a plasma processing method in which a substrate is supported on a substrate support within a plasma processing chamber. The substrate support is positioned at a first end of the plasma processing chamber. A plasma is electrically energized by a plasma generating electrode, which is positioned proximate a second end, opposite the first end, of the plasma processing chamber. The plasma is formed between the plasma generating electrode and the substrate. A pulsed DC waveform is applied to the substrate so as to bias the substrate at a first voltage and a second voltage. When the substrate is pulsed at the first voltage, positive ions are attracted from the plasma toward the substrate. Periodically, and when the substrate is pulsed at the second voltage, being less negative than the first voltage, electrons are attracted from the plasma toward the substrate.

Still another embodiment of the present invention is directed to a plasma etching apparatus that includes a plasma processing chamber and a substrate support positioned within and at a first end of the same. A plasma generating electrode is positioned proximate to a second end of the plasma processing chamber, which opposes the first end. The plasma generating electrode is operably coupled to a plasma generating electrode that is configured to energize the plasma generating electrode, which capacitively couples power into the plasma processing chamber to form a plasma. The plasma is positioned between the plasma generating electrode and the substrate. The substrate support is operably coupled to a DC pulse generator, which is configured to apply a pulsed DC bias voltage to a substrate positioned on the substrate support. The DC pulse generator periodically applies first and second voltages to the substrate such that during the first voltage, positive ions are attracted to the substrate and during the second voltage, electrons are attracted to the substrate.

While the present invention will be described in connection with certain embodiments, it will be understood that the present invention is not limited to these embodiments. To the contrary, this invention includes all alternatives, modifications, and equivalents as may be included within the scope of the present invention.

### BRIEF DESCRIPTION OF THE FIGURES

The accompanying drawings, which are incorporated in and constitute a part of this specification, illustrate embodiments of the present invention and, together with a general description of the invention given above, and the detailed description of the embodiments given below, serve to explain the principles of the present invention.

FIG. 1 is a schematic view of a chemical processing system in accordance with one embodiment of the present invention.

FIG. 2 is a graphical representation of a DC voltage waveform and an RF voltage waveform suitable for use in driving DC and RF voltage source of the system of FIG. 1 in accordance with one embodiment of the present invention.

FIG. 3 is a schematic view of a chemical processing system in accordance with another embodiment of the present invention.

FIG. 4A is a schematic view of a chemical processing system in accordance with another embodiment of the present invention.

FIG. 4B is a schematic view of an alternative to the chemical processing system of FIG. 4A.

FIG. 5A is a schematic view of a chemical processing system in accordance with still another embodiment of the present invention.

FIG. 5B is a schematic view of an alternative to the chemical processing system of FIG. 5A.

FIG. 6 is a schematic view of a chemical processing system in accordance with still another embodiment of the present invention.

FIG. 7 is a schematic view of a chemical processing system in accordance with another embodiment of the present invention.

### DETAILED DESCRIPTION

In the following description, to facilitate a thorough understanding of the invention and for purposes of explanation and not limitation, specific details are set forth, such as a particular geometry of the plasma processing system and various descriptions of the system components. However, it should be understood that the invention may be practiced with other embodiments that depart from these specific details.

Nonetheless, it should be appreciated that, contained within the description are features which, notwithstanding the inventive nature of the general concepts being explained, are also of an inventive nature.

According to one embodiment, a method and system for performing plasma-activated chemical processing of a substrate is provided, inter alia, to alleviate some or all of the above identified issues. Plasma-activated chemical processing includes kinetic energy activation (i.e., thermal charged species) and, hence, it achieves high reactive or etch efficiency. However, plasma-activated chemical processing, as provided herein, also achieves monochromatic or narrow band IED, mono-energetic activation, space-charge neutrality, and hardware practicality.

Referring now to the figures, and in particular to FIG. 1, a chemical processing system 10 according to one embodiment of the present invention is shown and described in detail. The chemical processing system 10 is configured to perform plasma-assisted or plasma-activated chemical processing of a substrate 12 positioned within a processing chamber 14 of the chemical processing system 10. The chemical processing system 10 further comprises a gas feed supply 16 that is fluidically coupled to the processing chamber 14 and is configured to supply one or more processing gases to the processing space 18 within the processing chamber 14 and above the substrate 12 when positioned on a substrate support 20. A vacuum pump 19 draws a vacuum on the processing space 18.

Three electrodes 22, 24, 26 reside within the processing chamber 14. The first electrode 22 may be incorporated into, or comprise, the substrate support 20 while the second electrode 24 is positioned within the processing chamber 14 and opposing the substrate 12. The third electrode 26, being optional, may be positioned along one or more walls of the processing chamber 14 and may be grounded.

The first electrode 22 is biased by a DC pulse from a DC pulse generator 28, while the second electrode 24 is included in a plasma source 30 and is actively powered. More particularly, and as specifically shown, the first electrode 22 is electronically coupled to ground through a negative DC voltage source 32 via, for example, a relay circuit 34, while the second electrode 24 is coupled to an AC voltage source 36 that may be an RF power supply.

In use, the AC voltage source 36 may be electronically coupled to the second electrode 24 via an impedance matching circuit 38 and is configured to apply a continuous AC power to the second electrode 24. For example, as shown in FIG. 2, a negative AC RF voltage 40 operating at 13.56 MHz, may be applied to the second electrode 24 for igniting a capacitively coupled plasma 42 within the processing space 18. Generally, the plasma 42, particularly the electrons within the plasma 42, are retained within the processing chamber 14 proximate the grounded third electrode 26. While the generic impedance matching circuit 38 is shown in this and other illustrative embodiments, one of ordinary skill in the art would readily appreciate that other manners of electrical connections may be used.

At a particular time interval, such as in accordance with a desired waveform, the relay circuit 34 coupled to the first electrode 22 is switched so as to apply a pulsed DC bias to the first electrode 22. For example, and as shown in FIG. 2, a pulsed negative bias 46 may be applied to the first electrode 22, during which positive ions are drawn toward the substrate 12. Pulsed periods of less negative bias 44 (even positive bias) applied to the first electrode 22 between the intervals of negative bias 46 draws electrons from the processing space 18, proximate the third electrode 26, toward the first electrode 22 and the substrate 12. As a result, the DC pulse bias achieves a mono-energetic ion excitation of the substrate 12 during the negative bias 46 and an energetic electron dump via a more positive bias 44 onto the substrate 12 to neutralize positive charge on the substrate 12. The waveform for the DC pulse (V_{RF}(t)) may vary in DC pulse frequency (from about 1 Hz to about 1 GHz and, more particularly from about 100 kHz to about 1 MHz) and duty cycle (from about 1% to about 99%) in which the fraction of the total pulse interval in which the DC pulse is applied and which may be adjusted to a particular energetic electron dump need, and where the pulse duty cycle is defined as the ratio of time of applied negative bias (i.e. to attract ions), to the total pulse period. Varying the duty cycle may be used to control how mono-energetic the ion excitation of the substrate is. In general, the duty cycle should be kept large enough to maintain as mono-energetic ion energies, as possible, without generation of any performance-degrading charge-up effects on the substrate. Due to the high mobility of electrons in the plasma, a duty cycle of 90%, 95%, or even 99% may provide sufficient time for electrons to provide neutralization of charge built from ion impingement, in any high aspect ratio (“HAR”) features present on the substrate.

With reference now to FIG. 3, a chemical processing system 50 in accordance with another embodiment of the present invention is shown and described in detail. The chemical processing system 50 is similar to that of FIG. 1, having the gas feed supply 16 (FIG. 1, not shown in FIG. 3A) to supply process gas to a processing space 52 and a vacuum pump 19 (FIG. 1, not shown in FIG. 3A) to draw a vacuum on the same. A substrate support 54 supports a substrate 56 within the chamber 58. Three electrodes 60, 62, 64 are also provided in the processing space 52 and oriented in the manner described previously with respect to the system 10 of FIG. 1. The second electrode 62, as shown, is divided in two parts such that the second electrode 62 includes a circular central electrode 62a and an annular peripheral electrode 62b surrounding and insulated from the central electrode 62a by an annular insulating ring 66. The second electrode 62 is coupled to an AC voltage source 68 via impedance matching circuit 70 and is configured to apply a separately controllable and continuous AC bias to the electrode parts 62a, 62b. The second electrode 62 is further coupled to the plasma source 72.

The first electrode 60, again shown as forming a portion of the substrate support 54, is electrically coupled to a DC voltage source 74 via a relay circuit 76, which is operable to be switched in the manner described in greater detail above. By segmenting the second electrode 62, greater control of plasma formation and uniformity may result. That is, the distribution of plasma formation may be controlled radially outwardly toward the walls of the processing space 52.

FIGS. 4A and 4B illustrate two related embodiments of the present invention. For illustrative convenience, like reference numerals having primes thereafter designate corresponding components of the embodiments. With specific reference to the embodiment of FIG. 4A, a chemical processing system 80 is shown and includes a processing chamber 82 that is generally similar to those described previously, although not all components are shown for illustrative convenience. The chemical processing system 80 includes three electrodes 84, 86, 88; however, the first electrode 84 of the instant chemical processing system 80 is alternately coupled to ground through the negative DC voltage source 90 or a parallel positive DC voltage source 92, via, a double throw relay circuit 94. The relay circuit 94 is switched so as to alternately apply a DC voltage function, for example, a negative bias followed by a positive bias, to the first electrode 84 to attract mono-energetic positive ions onto the substrate 96 during negative pulses, while the positive bias draws electrons or negative ions to the substrate 96 between the negative pulses to neutralize positive charge that may have accumulated on the substrate 96 during the negative pulses.

FIG. 4B is similar to FIG. 4A except that the second electrode 86′ is divided into a central portion 86a and a concentric outer portion 86b with an insulating ring 87 therebetween, as was described previously. It would be understood that the plasma generation source 98 with impedance matching circuit 100 of FIG. 4A may be configured to apply a separately controllable and continuous AC bias to the electrode parts 86a, 86b in FIG. 4B.

The plasma generating electrode need not be RF based. Instead, and as is shown in FIG. 5A, a chemical processing system 110 for processing a substrate 111 in accordance with yet another embodiment of the present invention, similar to that of FIG. 1 but with the plasma source 30 (FIG. 1) including a DC source 112 powering the second electrode 114 while the first and third electrodes 116, 118 electrically coupled to a DC voltage source 119 and ground, respectively, and has been discussed previously. With the DC source 112, the grounded third electrode 118, which is optional in embodiments wherein the plasma source applies an RF bias to the second electrode 24 (FIG. 1), is generally required. The third electrode 118 may comprise, in part, a grounded wall of the processing chamber 120, or may be a separately-constructed electrode that is then positioned inside, or in some configurations outside, the processing chamber 120.

FIG. 5B illustrates a chemical processing system 110′ that is similar to the chemical processing system 110 of FIG. 5A and in which like reference numerals having primes thereafter designate corresponding components of the embodiments. However, in FIG. 5B the second electrode 114′ is electronically coupled to ground through the negative DC voltage source 112′ via a relay circuit 122. In that regard, a pulsed DC voltage may also be applied to the second electrode 114′.

Additionally, FIG. 6 illustrates a chemical processing system 130 in accordance with another embodiment of the present invention and in which like reference numerals having primes thereafter designate corresponding components of the embodiments. The illustrative chemical processing system 130 is again similar to the system 10 of FIG. 1, but with the first electrode 22 being segmented to include a central circular segment 22a, an intermediate annular electrode segment 22b concentrically surrounding the central electrode segment 22a, and an outer electrode segment 22c concentrically surrounding the central and intermediate electrode segments 22a, 22b. The electrode segments 22a, 22b, 22c are separated by annular insulator rings 132, 134 and respectively biased by separate controllable DC bias voltage sources 74a, 74b, 74c via relay switches 76a, 76b, 76c. The DC sources 74a, 74b, 74c each apply pulsed DC voltages to the electrode segments 22a, 22b, 22c of the first electrode 22, typically at the same frequencies and in-phase, but adjusted, for example by varying pulse widths or duty cycle, to improve radial uniformity.

The conductivity of the substrate 12′ for use with the chemical processing system 130 of FIG. 6 having the electrically segmented first electrode 22′ should be less conductive than the substrates suitable for use with other embodiments.

FIG. 7 illustrates a chemical processing system 140 in accordance with still another embodiment of the present invention. Again, three electrodes 142, 144, 146 are operably coupled to a processing chamber 148. The first electrode 142 may support a substrate 150 within the processing chamber 148 while the second electrode 144 is positioned proximate a side of the processing chamber 148 that generally opposes the substrate 150.

The second electrode 144, as shown, is segmented and includes a central portion 144a, an intermediate portion 144b separated from the central portion 144a by a first annular insulator 152, and an outer portion 144c separated from the intermediate portion 144b by a second annular insulator 154. Each portion 144a, 144b, 144c of the second electrode 144 is respectively biased by separate controllable DC bias voltage sources 156a, 156b, 156c via relay switches 158a, 158b, 158c.

The first electrode 142 is electrically coupled to one or more AC voltage sources 160 having an RF power supply 162 therein. The AC voltage source 160 may be electronically coupled to the second electrode 144 via an impedance matching circuit 164 and is configured to apply a continuous AC bias to the second electrode 144.

The various embodiments of the present invention that are described in detail above provide a flux of ions onto a substrate having a narrow ion energy distribution. This is advantageous in many plasma processes, particularly in ion-activated chemical etching processes, where the energy of the ions is a factor in selecting the chemical process that will be activated. Chemical processes may therefore be selected and controlled by mono-energetic ions, i.e., if the energy distribution is narrow. With the present invention, this can be achieved by controlling the level of DC pulses used to bias the substrate.

Additionally, the buildup of positive charge on the substrate during ion bombardment, which occurs when bias voltage is more negative, may be neutralized by pulsing the bias on the substrate and controlling the more positive, or less negative, level of the pulsed waveform. The establishment of the pulse width (or duty cycle) of the waveform controls the amount of negative charge attracted to the substrate to neutralize the substrate. The charge may be electrons or, where the pulse width is sufficiently wide enough, negative ions when they are present in the plasma.

While the present invention has been illustrated by description of various embodiments and while those embodiments have been described in considerable detail, those skilled in the art will readily appreciate that many modifications are possible in the exemplary embodiment without materially departing from the novel teachings and advantages of this invention. The invention in its broader aspects is therefore not limited to the specific details and illustrative examples shown and described. Accordingly, departures may be made from such details without departing from the scope of the present invention.

What is claimed is:

1. A method of selectively activating a chemical process for plasma-assisted chemical etch processing of a substrate in a processing chamber, the method comprising:
coupling energy into a process gas within the processing chamber to produce a plasma therein, the plasma containing positive ions;
applying a pulsed DC bias to the substrate positioned on a substrate support in the processing chamber; and
periodically biasing the substrate positioned on the substrate support between first and second bias levels, the first bias level being more negative than the second bias level,
wherein the substrate and substrate support, when biased at the first bias level, attracts mono-energetic positive ions from the plasma toward the substrate and is operable to enhance a selected chemical etch process at a surface of the substrate.

2. The method of claim 1, further comprising:
periodically biasing the substrate positioned on the substrate support at the second bias level, the periodic biasing having a magnitude and a duration configured to attract negative charges from the plasma toward the substrate and is operable to neutralize accumulated positive charge on the surface of the substrate.

3. The method of claim 2, wherein the substrate support includes a DC pulsed biased electrode positioned on one end of the processing chamber, the processing chamber further comprising:
an actively powered plasma generating electrode positioned on a side of the processing chamber opposing the DC pulsed biased electrode and configured to capacitively couple the energy into the process gas.

4. The method of claim 3, wherein the plasma generating electrode is DC powered, the method further comprising:
providing a grounding electrode in the processing chamber that is operably coupled to the plasma.

5. The method of claim 3, wherein the plasma generating electrode is RF powered and configured to capacitively couple energy into the process gas.

6. The method of claim 2, wherein said second bias level is established at a potential that minimizes the attraction of ions from the plasma toward the substrate with energies that are different from energies of ions attracted from the plasma toward the substrate when the first bias level is established.

7. The method of claim 1, wherein the pulsed DC bias is applied at a frequency that ranges from about 50 kHz to about 40 MHz.

8. The method of claim 7, wherein the pulsed DC bias is applied at a frequency that ranges from about 10 MHz to about 20 MHz.

9. The method of claim 1, further comprising:
providing a grounding electrode in the processing chamber that is operably coupled to the plasma.

10. The method of claim 9, further comprising:
applying a changing potential to the grounding electrode by one of switching a voltage potential applied to the grounding electrode, applying a pulsed DC voltage to the grounding electrode, or applying an AC voltage to the grounding electrode.

11. A plasma processing method, comprising:
supporting a substrate on a substrate support within a plasma processing chamber and at a first end thereof;
electrically energizing a plasma generating electrode at a second end of the processing chamber to capacitively couple energy into producing a plasma between the plasma generating electrode and the substrate, the second end opposing the first end; and
biasing the substrate on the substrate support with a pulsed DC waveform, the pulsed DC waveform applying a first voltage to the substrate for attracting positive ions from the plasma and onto the substrate and, periodically, applying a second voltage to the substrate that attracts electrons from the plasma and onto the substrate, the first voltage being more negative than the second voltage.

12. The plasma processing method of claim 11, wherein the pulsed DC waveform has a duty cycle ranging from about 1% to about 99%.

13. The plasma processing method of claim 11, wherein the pulsed DC waveform has a duty cycle selected so as to maintain mono-energetic ion energies while minimizing a charge-up effect on the substrate.

14. The plasma processing method of claim 11, wherein the plasma generating electrode is energized by an RF power source operating at 13.56 MHz.

15. The plasma processing method of claim 11, wherein the pulsed DC bias is applied at a frequency that ranges from about 10 MHz to about 20 MHz.

16. A plasma etching apparatus, comprising:
a plasma processing chamber;
a substrate support positioned within the plasma processing chamber and proximate a first end thereof;
a plasma generating electrode positioned proximate a second end of the plasma processing chamber, the second end opposing the first end;
a power supply operably coupled to the plasma generating electrode and configured to energize the plasma generating electrode so as to capacitively couple power into the plasma processing chamber to form a plasma between the substrate and the plasma generating electrode; and
a DC pulse generator operably coupled to the substrate support and configured to apply a pulsed DC bias voltage to a substrate on the substrate support,
wherein the DC pulse generator is configured to apply a first voltage to the substrate support that is operable to attract positive ions from the plasma and onto the substrate and, periodically, to apply a second voltage to the substrate support that is operable to attract electrons from the plasma and onto the substrate, the first voltage being more negative than the second voltage.

17. The plasma etching apparatus of claim 16, wherein the power supply operably coupled to the plasma generating electrode is an RF voltage source configured to operate at 13.56 MHz.

18. The plasma etching apparatus of claim 16, wherein the power supply operably coupled to the plasma generating electrode is a DC voltage source.

19. The plasma etching apparatus of claim 18, wherein the DC voltage source is electrically coupled to the plasma generating electrode via a relay switch.

20. The plasma etching apparatus of claim 16, wherein the plasma generating electrode further comprises a plurality of segments, each of the plurality of segments being electrically isolated from other segments of the plurality.

21. The plasma etching apparatus of claim 20, wherein the segments of the plurality are driven by the same power supply.

22. The plasma etching apparatus of claim 20, wherein the power supply operably coupled to the plasma generating electrode further comprises a plurality of power supplies, each of the plurality of power supplies being operably coupled to a respective one of the plurality of segments.

23. The plasma etching apparatus of claim 16, further comprising:
a grounded electrode operably coupled to a wall of the plasma chamber and positioned between the plasma generating electrode and the substrate support.

24. The plasma etching apparatus of claim 16, wherein the substrate support further comprises a plurality of segments, each of the plurality of segments being electrically isolated from other segments of the plurality.

25. The plasma etching apparatus of claim 24, wherein the segments of the plurality are driven by the same power supply.

26. The plasma etching apparatus of claim 24, wherein the DC pulse generator further comprises a plurality of DC generators, each of the plurality of DC generators being operably coupled to a respective one of the plurality of segments.
